(19) United States
(12) Patent Application Publication
(10) Pub. No.: US 2012/0025829 A1
(43) Pub. Date: Feb. 2, 2012

(54) ACOUSTICALLY DAMPED GRADIENT COIL

(75) Inventors: Abdurrahman Abdallah Khalidi, Doha (QA); Robert Arvin Hedeen, Clifton Park, NY (US); Eric George Budesheim, Wynantskill, NY (US); Bruce Courtney Campbell Amm, Clifton Park, NY (US)

(73) Assignee: GENERAL ELECTRIC COMPANY, SCHENECTADY, NY (US)

(21) Appl. No.: 12/844,208

(22) Filed: Jul. 27, 2010

(51) Int. Cl. G01R 33/44; H01F 41/04

(52) U.S. Cl. 324/318; 29/602.1

(57) ABSTRACT

A gradient coil assembly is provided. The gradient coil assembly includes a cylindrical element. The cylindrical element has an inner surface and an outer surface. At least one first isolation material is disposed over the outer surface of the cylindrical element. A conducting material is disposed over the isolation material. A method to form the gradient coil assembly is also provided.

### BACKGROUND

1. Technical Field

The invention includes embodiments that relate to a gradient coil such as that used in a magnetic resonance imaging device. The invention includes embodiments that relate to a method of making the gradient coil for use in a magnetic resonance imaging device.

2. Discussion of Related Art

Magnetic resonance imaging (MRI) is a known technique for acquiring images of the inside of the body of an examination subject. In a MRI device, rapidly switched gradient fields that are generated by a gradient coil assembly are superimposed on a static basic magnetic field that is generated by a basic field magnet system. The MRI device also has a radio-frequency system that beams radio-frequency signals into the examination subject for triggering magnetic resonance signals and picks up the resulting magnetic resonance signals from which magnetic resonance images are produced.

For generating gradient fields, suitable currents must be set in gradient coils of the gradient coil system. The amplitudes of the required currents amount to up to several hundred amperes. The current rise and decay rates can be up to several hundred kilo amperes per second. Given a basic magnetic field of the order of magnitude of 1 Tesla, Lorentz forces that lead to oscillations of the gradient coil system act on these time-variable currents in the gradient coils. These oscillations are transmitted to the surface of the MRI device via various propagation paths. In case of a Z-gradient coil, the Lorenz forces are predominantly radial in direction with some axial component due to the curvature of the static basic magnetic field. At the surface, the mechanical oscillations are converted into acoustic oscillations that ultimately lead to unwanted noise that may exceed the ambient background noise. The excessive noise generated during an MRI procedure may be unsettling to patients and irritating to physicians and technicians.

A number of passive and active noise-reduction techniques have been proposed for magnetic resonance apparatuses. For example, known passive noise reduction measures include the application of foamed materials for lining components toward the gradient coil system and/or the use of flexible layers like rubber, at and/or in the gradient coil system.

It may be desirable to have an improved MRI device with reduced noise that differs from those devices that are currently available. It may be desirable to have a method of noise reduction for an MRI device that differs from those methods that are currently available.

### BRIEF DESCRIPTION

In accordance with an embodiment of the invention, a gradient coil assembly is provided. The gradient coil assembly includes a cylindrical element. The cylindrical element has an inner surface and an outer surface. At least one first isolation material is disposed over the outer surface of the cylindrical element. A conducting material is disposed over the isolation material.

In accordance with an embodiment of the invention, a gradient coil assembly is provided. The gradient coil assembly includes a cylindrical element. The cylindrical element has an inner surface and an outer surface. A first isolation material is disposed over the outer surface of the cylindrical element. A conducting material is disposed over the first isolation material. A second isolation material is disposed over the conducting material. The conducting material is disposed between the first isolation material and the second isolation material.

In accordance with an embodiment of the invention, a gradient coil assembly is provided. The gradient coil assembly includes a cylindrical element. The cylindrical element has an inner surface and an outer surface. A first isolation material is disposed over the outer surface of the cylindrical element. A second isolation material is disposed over the first isolation material. A conducting material is disposed over the second isolation material. A third isolation material is disposed over the conducting material. The conducting material is disposed between the second isolation material and the third isolation material.

In accordance with an embodiment of the invention, an apparatus is provided. The apparatus comprises at least one component contributing to generation of mechanical oscillations. The component comprises a cylindrical element, at least one first isolation material, and a conducting material. The cylindrical element has an inner surface and an outer surface. The isolation material is disposed over the outer surface of the cylindrical element. The conducting material is disposed over the isolation material.

In accordance with an embodiment of the invention, a magnetic resonance imaging device is provided. The device comprises a magnet and a gradient coil assembly located within the magnet. The gradient coil assembly includes a cylindrical element. The cylindrical element has an inner surface and an outer surface. At least one first isolation material is disposed over the outer surface of the cylindrical element. A conducting material is disposed over the isolation material.

In accordance with an embodiment of the invention, a gradient coil assembly is provided. The gradient coil assembly comprises a cylindrical element. The cylindrical element has an inner surface and an outer surface. A plurality of grooves are disposed on the outer surface of the cylindrical element; wherein the grooves comprise alternately disposed projections and recesses. A first isolation material comprising silicone, rubber, or compliant epoxy having compliance in a range from about 0.1 millimeters per Newton to about 1 millimeter per Newton is disposed over the outer surface of the cylindrical element such that the first isolation material is aligned with the recesses of the cylindrical element. A second isolation material comprising silicone, rubber, or compliant epoxy having compliance in a range from about 1 millimeter per Newton to about 10 millimeters per Newton is disposed over the outer surface of the cylindrical element. The second isolation material covers the projections on the outer surface of the cylindrical element and the first isolation material aligned with the recesses of the cylindrical element. A conducting material is disposed over the second isolation material. The conducting material is aligned with the recesses of the cylindrical element. A third isolation material comprising silicone, rubber, or compliant epoxy having compliance in a range from about 0.1 millimeters per Newton to about 1 millimeter per Newton is disposed over the conducting material. The conducting material is disposed between the second isolation material and the third isolation material.

In accordance with an embodiment of the invention, a method is provided. The method includes a first step of providing a cylindrical element having an inner surface and an outer surface. A first step includes disposing at least one first isolation material over the outer surface of the cylindrical element. A second step includes disposing a conducting material over the isolation material.

In accordance with an embodiment of the invention, a method is provided. The method includes a first step of providing a cylindrical element having an inner surface and an outer surface. A plurality of grooves are disposed on the outer surface of the cylindrical element. The grooves comprise alternately disposed projections and recesses. A second step includes disposing a first isolation material over the outer surface of the cylindrical element such that the first isolation material is aligned with the recesses of the cylindrical element. A third step includes disposing a second isolation material is disposed over the outer surface of the cylindrical element. The second isolation material covers the projections on the outer surface of the cylindrical element and the first isolation material aligned with the recesses of the cylindrical element. A fourth step includes disposing a conducting material over the second isolation material. The conducting material is aligned with the recesses of the cylindrical element. A fifth step includes disposing a third isolation material over the conducting material. The conducting material is disposed between the second isolation material and the third isolation material.

### BRIEF DESCRIPTION OF DRAWINGS

FIG. 1 is a schematic view showing a gradient coil assembly in accordance with one embodiment of the invention.

FIG. 2 is a schematic view showing a gradient coil assembly in accordance with one embodiment of the invention.

FIG. 3 is a schematic view showing a gradient coil assembly in accordance with one embodiment of the invention.

FIG. 4 is a schematic view showing a gradient coil assembly in accordance with one embodiment of the invention.

FIG. 5 is a schematic view showing a gradient coil assembly in accordance with one embodiment of the invention.

FIG. 6 is a schematic view showing a gradient coil assembly in accordance with one embodiment of the invention.

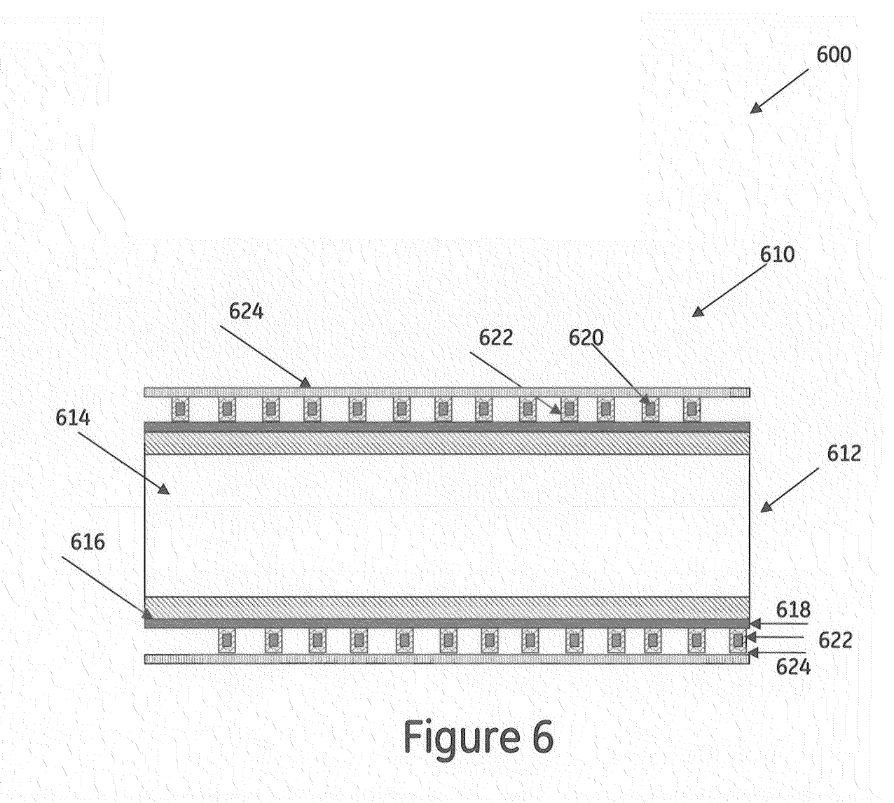

FIG. 7 is a schematic view showing a cylindrical element in accordance with one embodiment of the invention.

FIG. 8 is a schematic view showing a gradient coil assembly in accordance with one embodiment of the invention.

FIG. 9 is a schematic view showing a gradient coil assembly in accordance with one embodiment of the invention.

FIG. 10 is an isometric view showing an MRI device in accordance with one embodiment of the invention.

FIG. 11 is a method of forming a gradient coil assembly in accordance with one embodiment of the invention.

FIG. 12 is a method of forming a gradient coil assembly in accordance with one embodiment of the invention.

FIG. 13 is a schematic view of a cylindrical element in accordance with an embodiment of the invention.

FIG. 14 is a schematic view of a cylindrical element in accordance with an embodiment of the invention.

FIG. 15 is a schematic view of a cylindrical element in accordance with an embodiment of the invention.

FIG. 16 is a schematic view of a cylindrical element in accordance with an embodiment of the invention.

FIG. 17 is a schematic view of a cylindrical element in accordance with an embodiment of the invention.

FIG. 18 is a schematic view of a cylindrical element in accordance with an embodiment of the invention.

FIG. 19 is a schematic view of a cylindrical element in accordance with an embodiment of the invention.

FIG. 20 is a schematic view of a cylindrical element in accordance with an embodiment of the invention.

FIG. 21 is a graph illustrating the vibration at resonance of a gradient coil assembly in accordance with an embodiment of the invention.

FIG. 22 is a graph illustrating the air-borne noise of the gradient coil assembly in accordance with an embodiment of the invention.

### DETAILED DESCRIPTION

The invention includes embodiments that relate to a gradient coil such as that used in a magnetic resonance imaging device. The invention includes embodiments that relate to a method of making the gradient coil for use in a magnetic resonance imaging device.

As discussed above, the vibrations caused during the operation of an MRI device result in the production of airborne noise that may constitute an annoyance to the patient, the operating staff and other persons in the vicinity of the MRI device. The vibrations of the gradient coil and of the magnet, and their transmission to an RF resonator and a patient couch in the interior of the magnet and/or the gradient coil, are expressed in inadequate clinical image quality which can even lead to misdiagnosis, especially in the case of functional imaging, fMRI. Costs are also incurred for providing a vibration-isolation system setup to prevent transmission of the vibrations to the ground, or vice versa.

Embodiments of the invention described herein address the noted shortcomings of the state of the art. The gradient coil assembly described herein fills the needs described above by providing an improved vibroacoustic isolation of vibrating conductors. These gradient coils could potentially offer MRI devices with reduced noise levels and hence provide MRI devices that provide better images. Conductors inside the gradient coil experience large Lorenz forces due to the interaction of the AC current with the static field of the magnet. Embodiments disclosed herein provide a gradient coil assembly wherein a conducting material is mechanically isolated from a cylindrical element on which the conducting material is wound. The isolation is done by using layers of isolation materials so that less vibration will be transmitted to the structure when the conductors deflect under the influence of the Lorenz forces. The advantage of this approach is that it reduces structure-borne noise at the source rather than dealing with noise itself. The gradient coil assembly disclosed herein is formed by disposing at least one layer of an isolation material on the surface of a cylindrical element that forms the gradient coil assembly. A conducting material is disposed over the first isolation material. In certain embodiments a second isolation material is disposed over the conducting material such that the conducting material is disposed between the first isolation material and the second isolation material. A third isolation material may be disposed over second isolation material. In certain embodiments, the second isolation material may be disposed over the first isolation material, the conducting material is disposed over the second isolation material, and the third isolation material may be disposed over the conducting material in manner such that the conducting material is disposed between the second isolation material and the third isolation material. Depositing the layers of isolation materials and depositing the conducting material over or in between the isolation materials allows the conducting material to vibrate over the isolation material without further transmission of vibration from the gradient coil assembly to other parts of the apparatus of the device.

One or more specific embodiments of the present invention will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present invention, the articles “a,” “an,” “the,” and “said” are intended to mean that there are one or more of the elements. The terms “comprising,” “including,” and “having” are intended to be inclusive and mean that there may be additional elements other than the listed elements. Moreover, the use of “top,” “bottom,” “above,” “below,” and variations of these terms is made for convenience, but does not require any particular orientation of the components unless otherwise stated. As used herein, the terms “disposed over” or “deposited over” or “disposed between” refers to both secured or disposed directly in contact with and indirectly by having intervening layers there between.

As used herein, the phrase “isolation material” refers to a highly compliant elastomeric material used to allow vibrating elements to move freely relative to their surroundings and not transmit their vibrational energy. As known to one skilled in the art, up to a certain limit there is a linear relationship between the force (F) applied to a material and the extent to which the material deforms (D). Hook's law provides an equation

D/F=C I

wherein C is a constant, and is defined as the compliance of the material in millimeters per Newton. For example, if a cord needs 1256 Newton (F) to be extended by 20 millimeters (D), C is equal to about 0.016 millimeters per Newton (20/1256), or 16 micrometers per Newton. To be effective in this application the isolation material should have a mechanical compliance value of at least 10 times that of the surrounding material. The isolation material may additionally possess damping properties to further remove energy from the vibrating elements themselves. A compliant isolation material that includes a damping loss factor of at least 0.02 would be additionally effective in this application.

Approximating language, as used herein throughout the specification and claims, may be applied to modify any quantitative representation that could permissibly vary without resulting in a change in the basic function to which it may be about related. Accordingly, a value modified by a term such as “about” is not limited to the precise value specified. In some instances, the approximating language may correspond to the precision of an instrument for measuring the value.

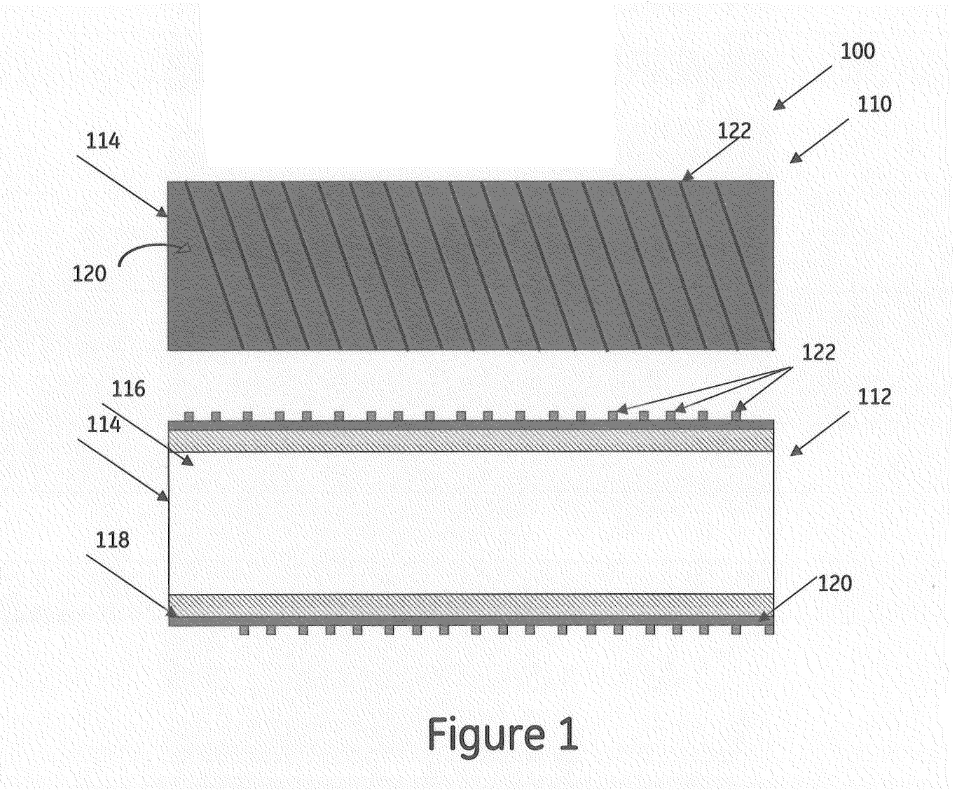

In one embodiment, a gradient coil assembly 100 is provided. Referring to FIG. 1 a schematic top view 110 and a cross sectional view 112 of the gradient coil assembly 100 is provided. The gradient coil assembly 100 includes a cylindrical element 114. The cylindrical element 114 has an inner surface 116 and an outer surface 118. At least one first isolation material 120 is disposed over the outer surface 118 of the cylindrical element 114. A conducting material 122 is disposed over the isolation material 120 thus isolating the conducting material 122 from being in direct contact with the outer surface 118 of the cylindrical element 114. In one embodiment, a protective covering (not shown in figure) may be disposed over the second isolation material. In one embodiment, an insulating covering (not shown in figure) may be disposed over the protective covering. In one embodiment, the cylindrical element 110 may comprise any material known to one skilled in the art as useful for a cylindrical element in a gradient coil assembly. In one embodiment, the cylindrical element 110 comprises epoxy or fiberglass.

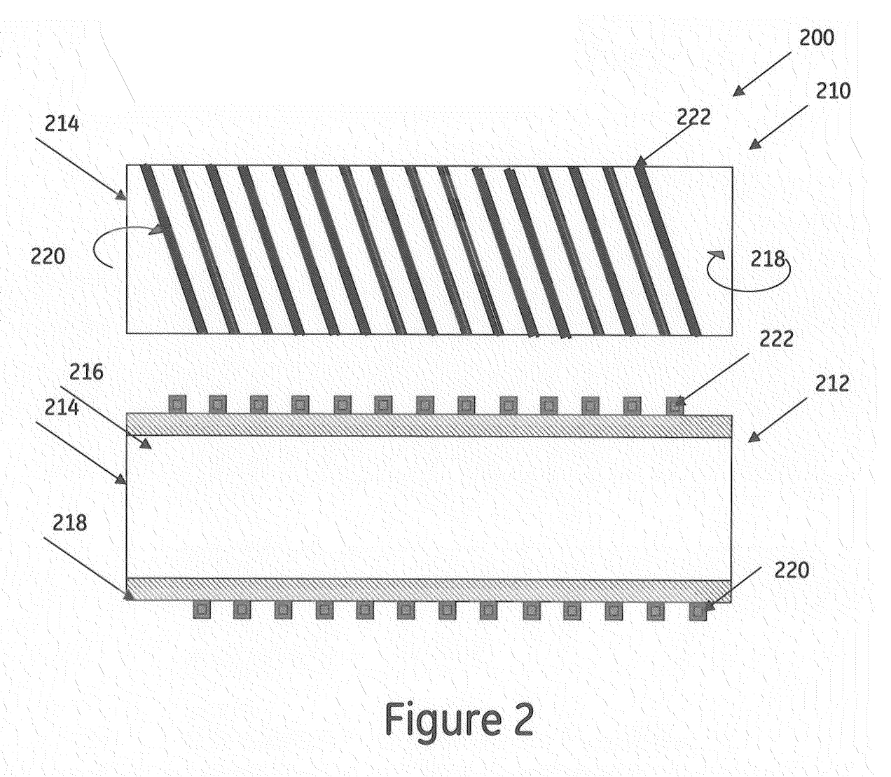

In one embodiment, a gradient coil assembly 200 is provided. Referring to FIG. 2 a schematic top view 210 and a cross sectional view 212 of the gradient coil assembly 200 is provided. The gradient coil assembly 200 includes a cylindrical element 214. The cylindrical element 214 has an inner surface 216 and an outer surface 218. At least one first isolation material 220 is disposed over a conducting material 222. The isolation material 220 is disposed in a manner such that the isolation material 220 forms a sleeve or encapsulation over the conducting material 222. The conducting material 222 encapsulated in the isolation material 220 is then wound round the cylindrical element 214. The isolation material 220 thus isolates the conducting material 222 from being in direct contact with the outer surface 218 of the cylindrical element 214. In one embodiment, a protective covering (not shown in figure) may be disposed over the second isolation material. In one embodiment, an insulating covering (not shown in figure) may be disposed over the protective covering.

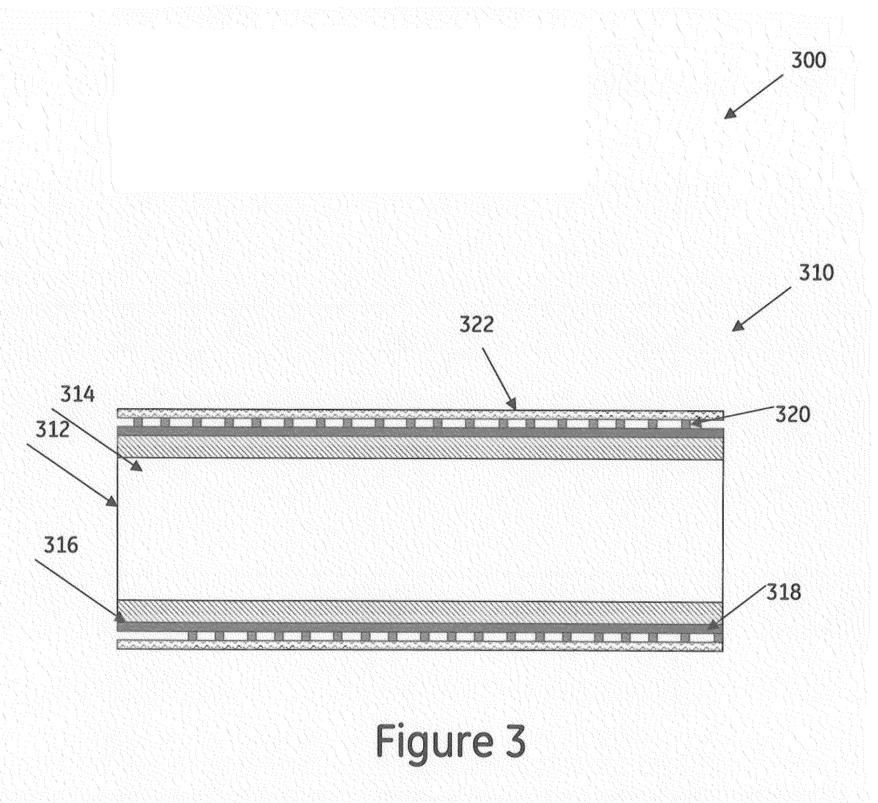

In one embodiment, a gradient coil assembly 300 is provided. Referring to FIG. 3 a schematic cross sectional view 310 of the gradient coil assembly 300 is provided. The gradient coil assembly 300 includes a cylindrical element 312. The cylindrical element 312 has an inner surface 314 and an outer surface 316. A first isolation material 318 is disposed over the outer surface 316 of the cylindrical element 312. A conducting material 320 is disposed over the first isolation material 318. A second isolation material 322 is disposed over the conducting material 320 such that the conducting material 320 is disposed between the first isolation material 318 and the second isolation material 322. The first isolation material 318 and the second isolation material 322 together assist in isolating the conducting material 320 from being in direct contact with the outer surface 316 of the cylindrical element 312. In one embodiment, a protective covering (not shown in figure) may be disposed over the second isolation material. In one embodiment, an electrically insulating covering (not shown in figure) may be disposed over the protective covering.

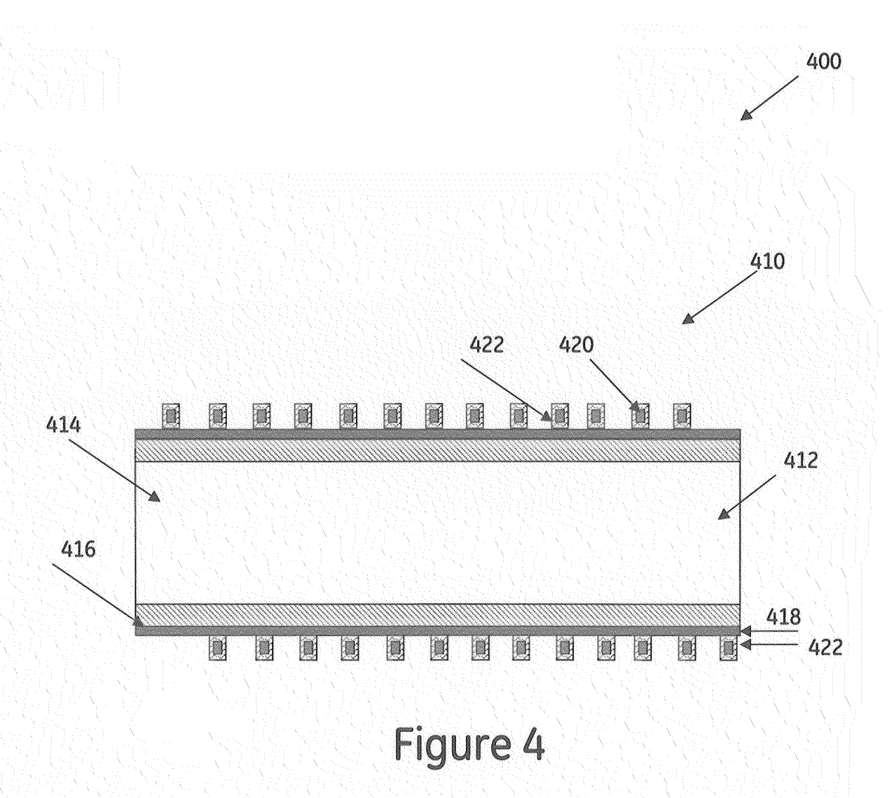

In one embodiment, a gradient coil assembly 400 is provided. Referring to FIG. 4 a schematic cross sectional view 410 of the gradient coil assembly 400 is provided. The gradient coil assembly 400 includes a cylindrical element 412. The cylindrical element 412 has an inner surface 414 and an outer surface 416. A first isolation material 418 is disposed over the outer surface 416 of the cylindrical element 412. A second isolation material 422 is disposed over a conducting material 420 in a manner such that the second isolation material 422 forms a sleeve or encapsulation over the conducting material 420. The conducting material 420 encapsulated in the first isolation material 418, is then wound round the first isolation material 418. The first isolation material 418 and the second isolation material 422 thus isolate the conducting material 420 from being in direct contact with the outer surface 416 of the cylindrical element 412. In one embodiment, a protective covering (not shown in figure) may be disposed over the second isolation material. In one embodiment, an insulating covering (not shown in figure) may be disposed over the protective covering.

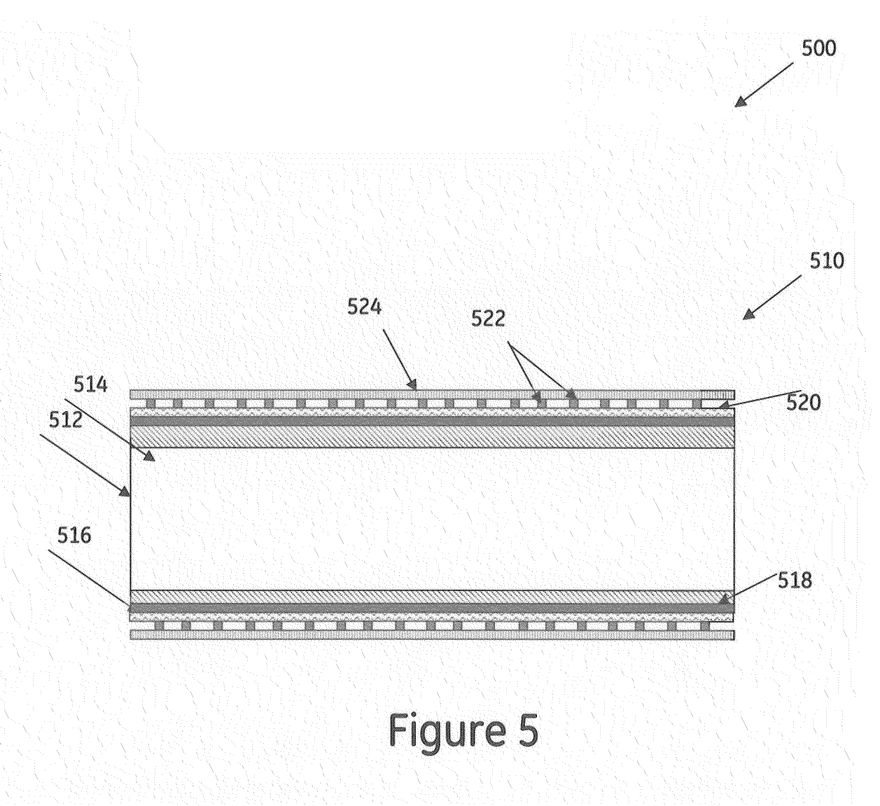

In one embodiment, a gradient coil assembly 500 is provided. Referring to FIG. 5 a schematic cross sectional view 510 of the gradient coil assembly 500 is provided. The gradient coil assembly 500 includes a cylindrical element 512. The cylindrical element 512 has an inner surface 514 and an outer surface 516. A first isolation material 518 is disposed over the outer surface 516 of the cylindrical element 512. A second isolation material 520 is disposed over the first isolation material 518. A conducting material 522 is disposed over the second isolation material 520. A third isolation material 524 is disposed over the conducting material 522 such that the conducting material 522 is disposed between the second isolation material 520 and the third isolation material 524. The first isolation material 518, the second isolation material 520, and the third isolation material 524 together assist in isolating the conducting material 522 from being in direct contact with the outer surface 516 of the cylindrical element 512. In one embodiment, a protective covering (not shown in figure) may be disposed over the second isolation material. In one embodiment, an insulating covering (not shown in figure) may be disposed over the protective covering.

In one embodiment, a gradient coil assembly 600 is provided. Referring to FIG. 3 a schematic cross sectional view 610 of the gradient coil assembly 600 is provided. The gradient coil assembly 600 includes a cylindrical element 612. The cylindrical element 612 has an inner surface 614 and an outer surface 616. A first isolation material 618 is disposed over the outer surface 616 of the cylindrical element 612. A conducting material 620 is disposed over the first isolation material 618. A second isolation material 622 is disposed over the conducting material 620 such that the second isolation material 622 forms a sleeve over the conducting material 620, as described in FIG. 2 above. A third isolation material 624 is then disposed over the second isolation material 622 and the conducting material 620. The first isolation material 618, the second isolation material 622, and the third isolation material 624 together assist in isolating the conducting material 620 from being in direct contact with the outer surface 616 of the cylindrical element 612. In one embodiment, a protective covering (not shown in figure) may be disposed over the second isolation material. In one embodiment, an insulating covering (not shown in figure) may be disposed over the protective covering.

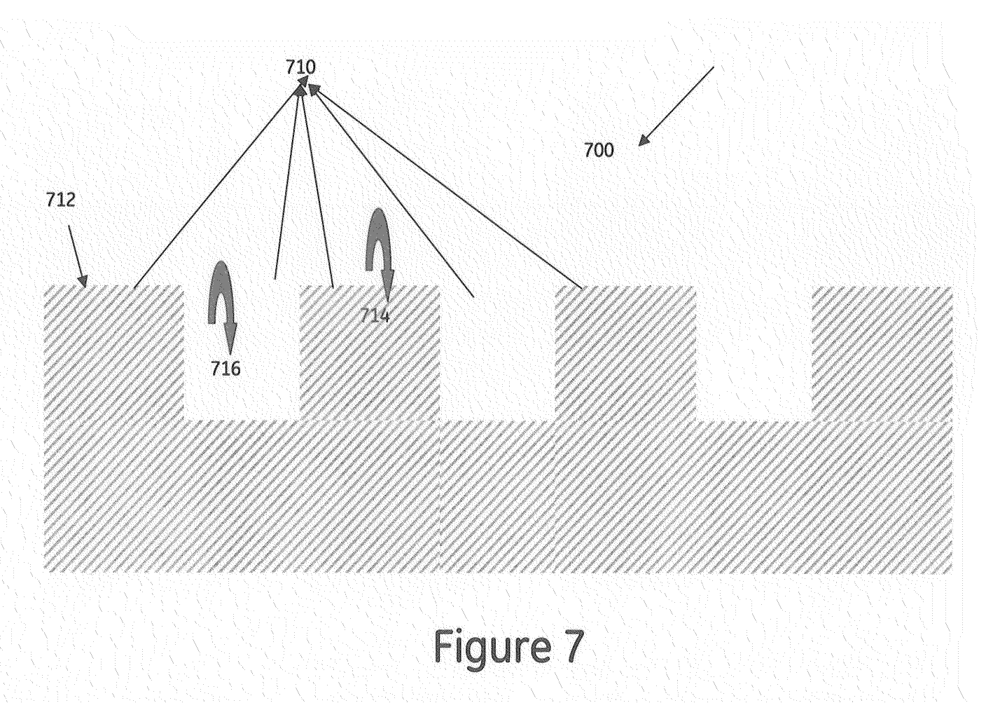

In one embodiment, a cylindrical element 700 comprises a plurality of grooves 710 disposed on the outer surface of the cylindrical element 700. Referring to FIG. 7, a schematic view of a cross section of a cylindrical element 700 is provided. A plurality of grooves 710, are disposed on the outer surface 712 of the cylindrical element 700. The grooves comprise alternately disposed projections 714 and recesses 716.

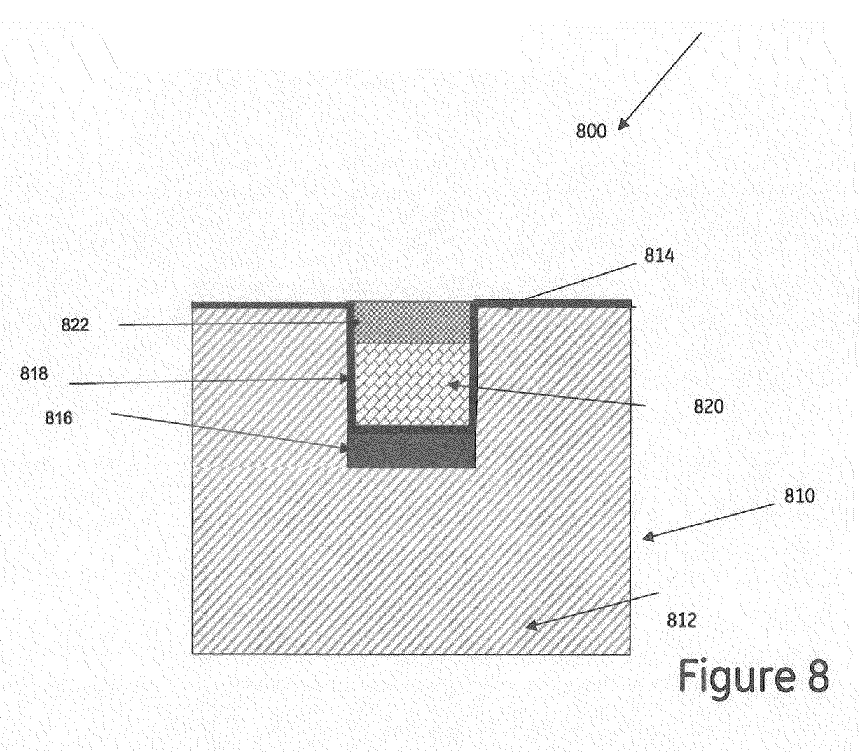

In one embodiment, a gradient coil assembly 800 is provided. Referring to FIG. 8 a schematic view of a cross section of the gradient coil assembly 800 is provided. The gradient coil assembly 800 includes a cylindrical element 810. The cylindrical element 810 has an inner surface 812 and an outer surface 814. A first isolation material 816 is disposed over the outer surface 814 of the cylindrical element 810. A second isolation material 818 is disposed over the first isolation material 816. A conducting material 820 is disposed over the second isolation material 818. A third isolation material 822 is disposed over the conducting material 820. The conducting material 820 is disposed between the second isolation material 818 and the third isolation material 822.

In one embodiment, the conducting material comprises at least one metal selected from group VIIIB, group IB, or group IIIA of the periodic table. In one embodiment, the conducting material comprises copper, gold, silver, or aluminum. In one embodiment, the conducting material comprises copper.

In various embodiments, the first isolation material 120, 220, 318, 418, 518, 618, 816, the second isolation material 322, 422, 522, 622, 818 and the third isolation material 524, 624, 822 employed in the gradient coil assemblies 100, 200, 300, 400, 500, 600, 800 discussed above include highly compliant materials that can assist in mechanical isolation of vibration. In one embodiment, the first isolation material comprises a material having compliance greater than about 0.1 millimeters. In another embodiment, the first isolation material comprises a material having compliance greater than about 0.2 millimeters. In yet another embodiment, the first isolation material comprises a material having compliance greater than about 0.3 millimeters. In one embodiment, the first isolation material comprises a material, having compliance in a range from about 0.1 millimeters per Newton to 1.0 millimeter per Newton. In another embodiment, the first isolation material comprises a material having compliance in a range from about 0.2 millimeters per Newton to 0.9 millimeters per Newton. In yet another embodiment, the first isolation material comprises a material having compliance in a range from about 0.3 millimeters per Newton to 0.8 millimeters per Newton. In some embodiments, the first isolation material comprises a material, having compliance in a range bounded by any combination of upper and lower limits as described above.

In one embodiment, the first isolation material comprises silicone, rubber, or epoxy. In one embodiment, the first isolation material comprises silicone, having compliance of greater than about 0.1 millimeters. In one embodiment, the first isolation material comprises silicone, having compliance in a range from about 0.1 millimeters per Newton to 1.0 millimeter per Newton. In one embodiment, the first isolation material may be shaped in the form of a cord or a sheet.

In one embodiment, the second isolation material 322, 422, 522, 622, 818 comprises a material having compliance, of greater than about 1 millimeter. In another embodiment, the second isolation material comprises a material having compliance, of greater than about 2 millimeter. In yet another embodiment, the second isolation material comprises a material having compliance, of greater than about 3 millimeter. In one embodiment, the second isolation material comprises a material having compliance, in a range from about 1 millimeter per Newton to 10 millimeters per Newton. In another embodiment, the second isolation material comprises a material compliance in a range from about 2 millimeters per Newton to 9 millimeters per Newton. In yet another embodiment, the second isolation material comprises a material compliance in a range from about 3 millimeters per Newton to 8 millimeters per Newton. In some embodiments, the first isolation material comprises a material, having compliance in a range bounded by any combination of upper and lower limits as described above.

In one embodiment, the second isolation material comprises rubber. In one embodiment, the second isolation material comprises rubber, having compliance in a range from about 1 millimeter per Newton to 10 millimeters per Newton. In one embodiment, the second isolation material may be shaped in the form of a sheet.

In one embodiment, the third isolation material 524, 624, 822 comprises a material having compliance greater than about 0.1 millimeters. In another embodiment, the third isolation material comprises a material having compliance greater than about 0.2 millimeters. In yet another embodiment, the third isolation material comprises a material having compliance greater than about 0.3 millimeters. In one embodiment, the third isolation material comprises a material having compliance in a range from about 0.1 millimeters per Newton to 1.0 millimeter per Newton. In another embodiment, the third isolation material comprises a material having compliance in a range from about 0.2 millimeters per Newton to 0.9 millimeters per Newton. In yet another embodiment, the third isolation material comprises a material having compliance in a range from about 0.3 millimeters per Newton to 0.8 millimeters per Newton. In some embodiments, the third isolation material comprises a material, having compliance in a range bounded by any combination of upper and lower limits as described above.

In one embodiment, the third isolation material comprises silicone, rubber or epoxy. In one embodiment, the third isolation material comprises silicone, having compliance in a range from about 0.1 millimeters per Newton to 1 millimeter per Newton. In one embodiment, the third isolation material may be shaped in the form of a cord or a sheet.

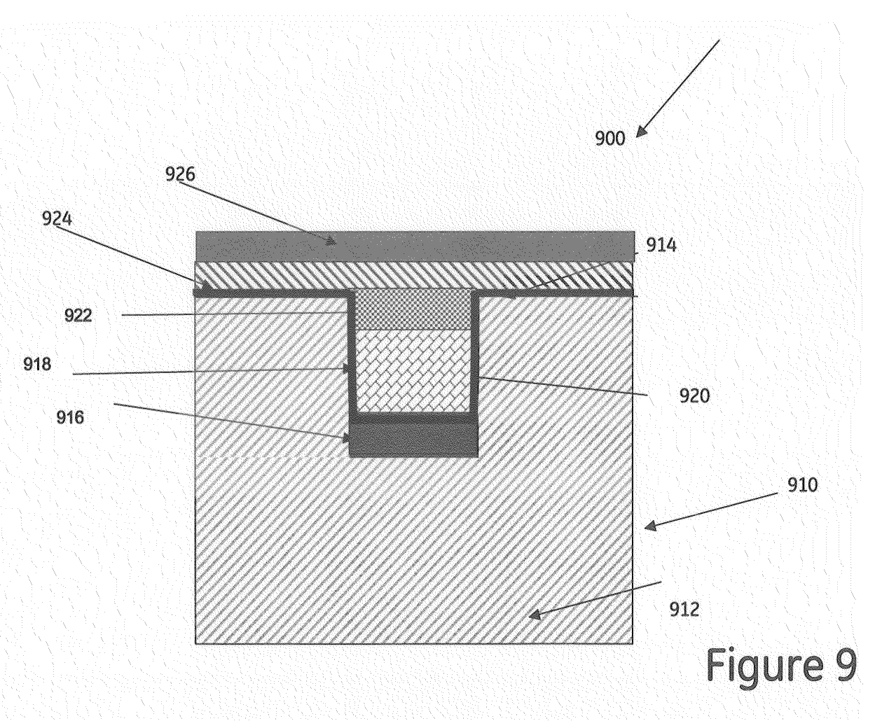

In one embodiment, a gradient coil assembly 900 may be covered with a protecting covering 924. In one embodiment, an insulating covering 926 may be disposed over the protective covering 924. The protective covering 924 functions to hold in place the layers of isolation materials 916, 918, and 922 and the conducting material 920 that are disposed over the cylindrical element 910. Referring to FIG. 9, a schematic view of a cross section of the gradient coil assembly 900 is provided. The gradient coil assembly 900 includes a cylindrical element 910. The cylindrical element 910 has an inner surface 912 and an outer surface 914. A first isolation material 916 is disposed over the outer surface 914 of the cylindrical element 910. A second isolation material 918 is disposed over the first isolation material 916. A conducting material 920 is disposed over the second isolation material 918. A third isolation material 922 is disposed over the conducting material 920. The conducting material 920 is disposed between the second isolation material 918 and the third isolation material 922. A protective covering 924 is disposed over the surface of the gradient coil assembly 900 such that the protective covering covers the cylindrical element and the isolation materials and conducting materials disposed over the cylindrical element. An insulating covering 926 is then disposed over the protective covering. In one embodiment, the protective covering 924 comprises a polymer material. In one embodiment, the insulating covering 926 comprises an epoxy layer. In one embodiment, one embodiment, the insulating covering 926 comprises fiberglass. In one embodiment, the protective covering 922 is provided to prevent the insulating covering 926 from coming in contact with the isolation materials 916, 918, 922 or the conducting material 920 during the initial curing process when the insulating covering, for example, an epoxy or a fiberglass covering is in a viscous liquid state. In various embodiments, the material used to form the insulating covering 926 may have a much lower compliance than the isolation materials 916, 918 and 922 and may hence lead to reducing the effectiveness of the isolation materials if the insulating covering were to come into contact with the conducting material.

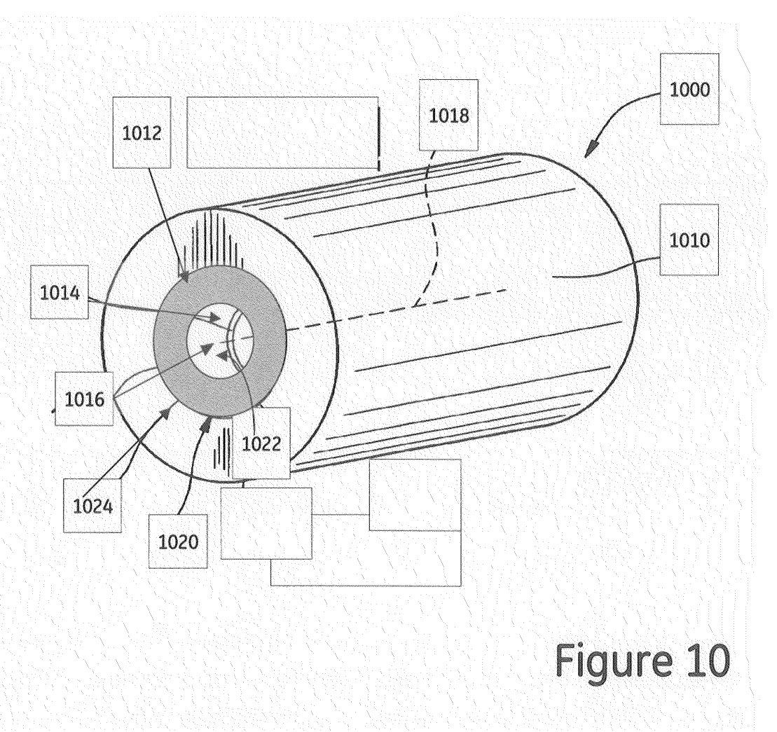

One embodiment is an MRI device 1000 comprising a gradient coil assembly. The gradient coil assembly may include any of the gradient coils 100-600, 800, and 900. Referring to FIG. 10, an isometric view of a MRI device is provided. The MRI device 1000 includes a magnet assembly 1010 that surrounds a gradient coil assembly 1012, and a radio frequency (RF) coil assembly 1014. The RF coil assembly may be separate stand along tube disposed within the MRI device 1000. A patient positioning area 1016 is defined through the MRI device 1000 through the longitudinal axis 1018. The gradient coil assembly 1012 comprises a cylindrical element 1020 having an inner surface 1022 and an outer surface 1024. At least one first isolation material 120, and a conducting material 122 are disposed on the outer surface 1024 of the cylindrical element 1020. During operation of the MRI device 1000 the magnet assembly 1010 provides a static magnetic field while the gradient coil assembly 1012 generates a magnetic filed gradient for use in producing magnetic resonance images. The RF coil assembly 1014 transmits a radio frequency pulse and detects a plurality of MR signals induced from a subject being imaged. In particular, the isolation material 120 assists in reducing the vibroacoustic energy, and therefore acoustic noise, produced by vibrations of the gradient coil assembly 1012 during an imaging procedure. The reduced amount of acoustic noise produced by the MRI device 1000 provides a more patient friendly system and method of MRI.

In accordance with an embodiment of the invention, a magnetic resonance imaging device 1000 is provided. The device 1000 comprises a magnet 1010 and a gradient coil assembly 1012 located within the magnet. The gradient coil assembly 1012 includes a cylindrical element 114. The cylindrical element 114 has an inner surface 116 and an outer surface 118. A first isolation material 120 is disposed over the outer surface 118 of the cylindrical element 114. A conducting material 122 is disposed over the isolation material 120. The conducting material 122 is isolated from the outer surface 118 of the cylindrical element 114 by the isolation material 120.

In accordance with an embodiment of the invention, an apparatus is provided. In one embodiment, the apparatus comprises a MRI device 1000. The apparatus comprises at least one component contributing to generation of mechanical oscillations. The component includes a cylindrical element 114. The cylindrical element 114 has an inner surface 116 and an outer surface 118. A first isolation material 120 is disposed over the outer surface 118 of the cylindrical element 114. A conducting material 122 is disposed over the isolation material 120. The conducting material 122 is isolated from the outer surface 118 of the cylindrical element 114 by the isolation material 120. The component includes a gradient coil assembly that may include any of the gradient coils 100-600, 800, and 900.

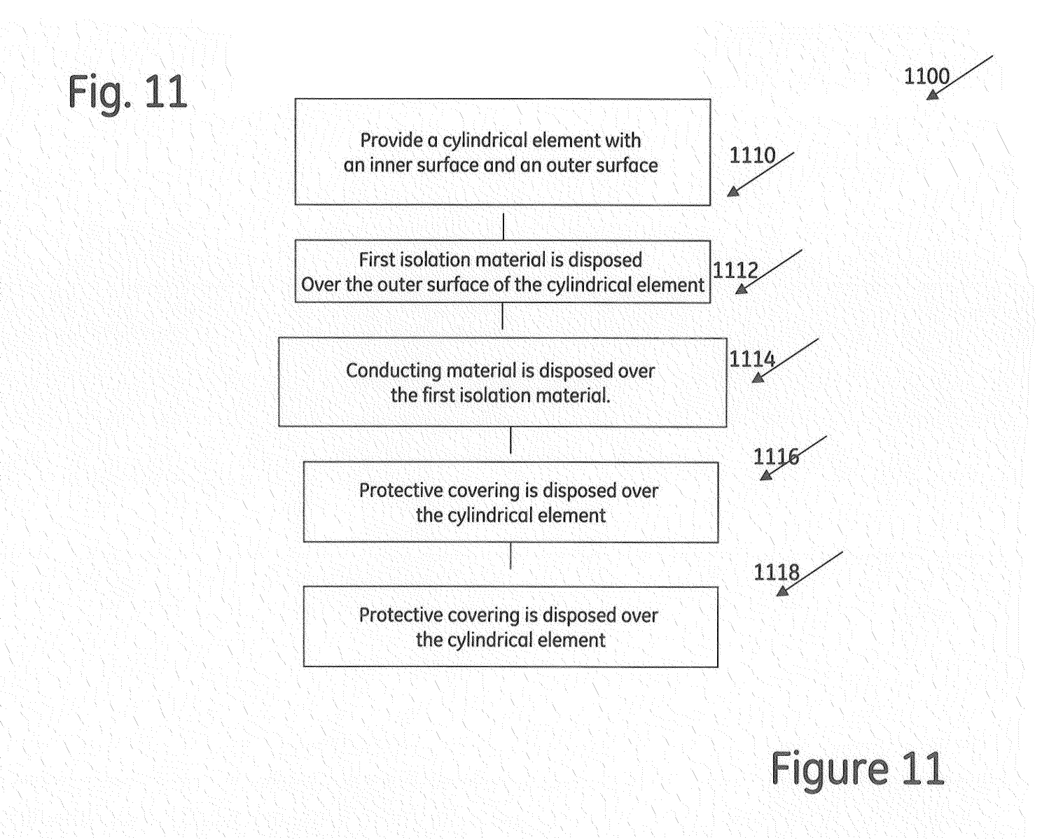

In accordance with an embodiment of the invention, a method 1100 of forming a gradient coil assembly in accordance with one embodiment of the invention is provided. Referring to FIG. 11, the method includes a first step 1110 of providing a cylindrical element having an inner surface 116 and an outer surface 118. A second step 1112 includes disposing a first isolation material 120 over the outer surface 118 of the cylindrical element 114. A third step 1114 includes disposing a conducting material 122 over the first isolation material 120. A fourth step 1116 includes disposing a layer of a protective covering 924 on the surface of the cylindrical element 114. A fifth step includes disposing a layer of a insulating covering 926 over the protective coating 924.

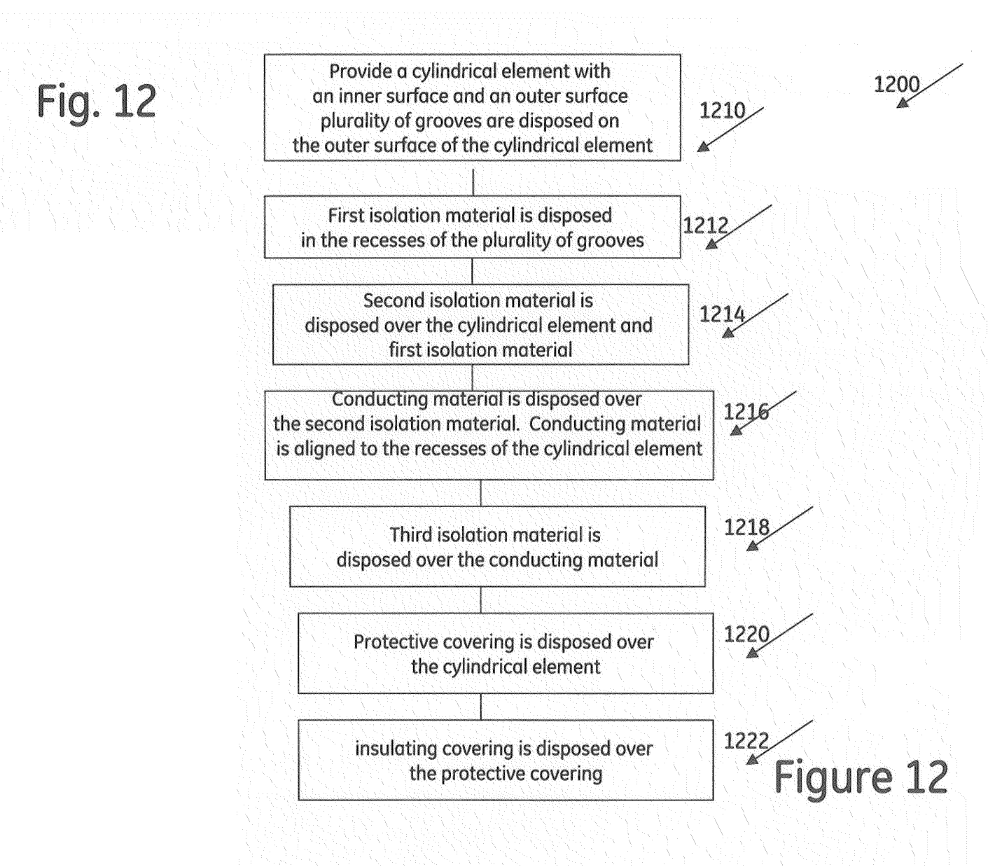

In accordance with an embodiment of the invention, a method 1200 of forming a gradient coil assembly in accordance with one embodiment of the invention is provided. Referring to FIG. 12, the method includes a first step 1210 of providing a cylindrical element 910 having an inner surface 912 and an outer surface 914. A plurality of grooves 710 are disposed on the outer surface 914 of the cylindrical element 910. The grooves 710 comprise alternately disposed projections 714 and recesses 716. A second step 1212 includes disposing a first isolation material 916 over the outer surface 114 of the cylindrical element 910 such that the first isolation material 916 is aligned with the recesses 716 of the cylindrical element 910. A third step 1214 includes disposing a second isolation material 918 over the outer surface 914 of the cylindrical element 910 and the first isolation material 916 such that the second isolation material 918 covers the projections 714 on the outer surface 914 of the cylindrical element 910 and the first isolation material 916. A fourth step 1216 includes disposing a conducting material 920 over the second isolation material 918. The conducting material 920 is aligned with the recesses 716 of the cylindrical element 910. A fifth step 1218 includes disposing a third isolation material 922 over the conducting material 920. The conducting material 920 is disposed between the second isolation material 918 and the third isolation material 922. A sixth step 1218 includes disposing a layer of a protective covering 924 on the surface of the cylindrical element 912. A seventh step includes disposing a layer of a insulating covering 926 over the protective coating 924. As used herein, the terms “first step”, “second step” etc., are meant merely to distinguish the steps and do not imply a mandated ordering of steps. Nor do these terms imply that intermediate steps could not be inserted between the enumerated steps.

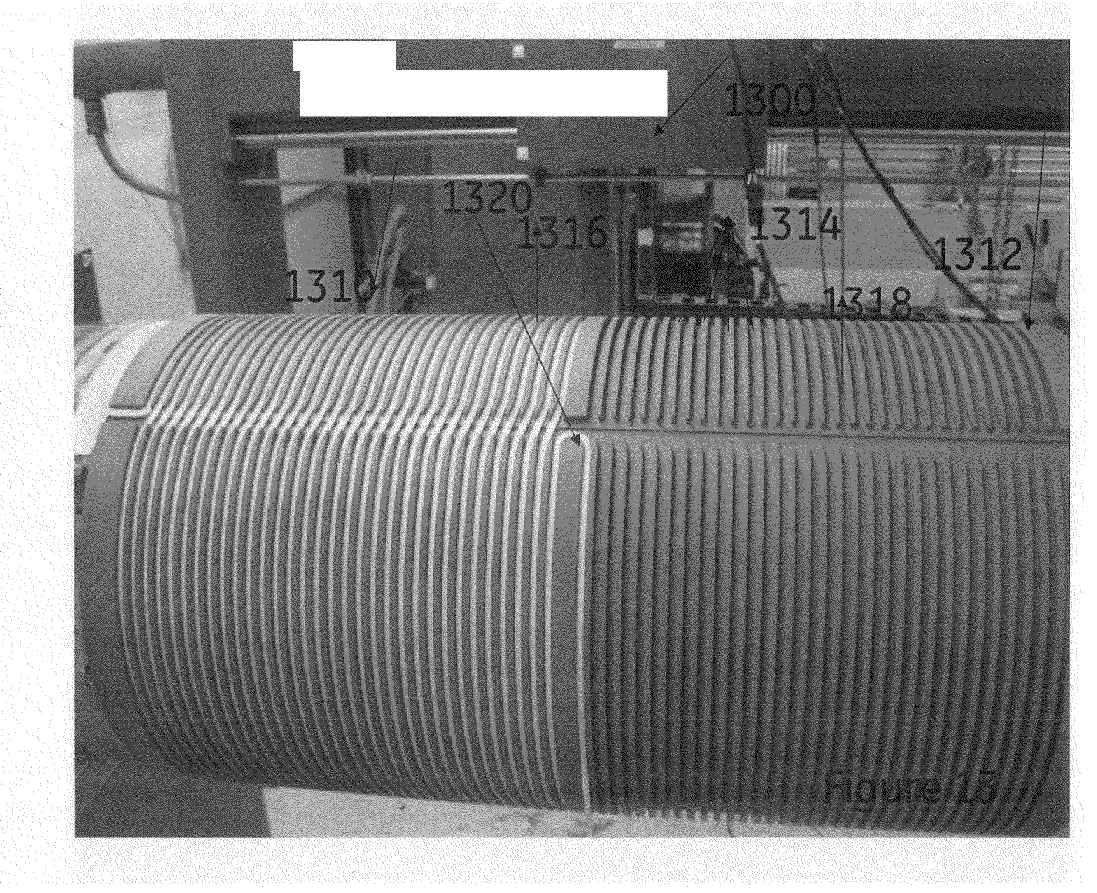

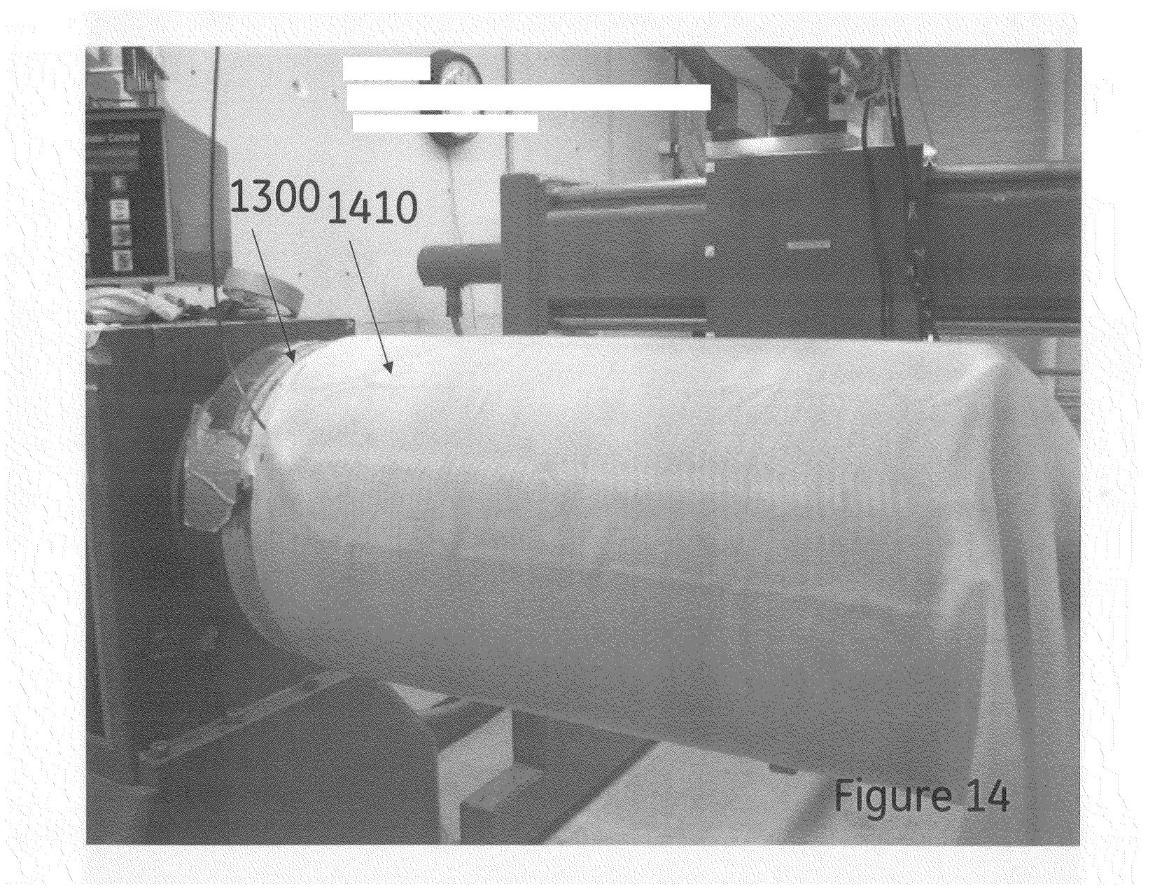

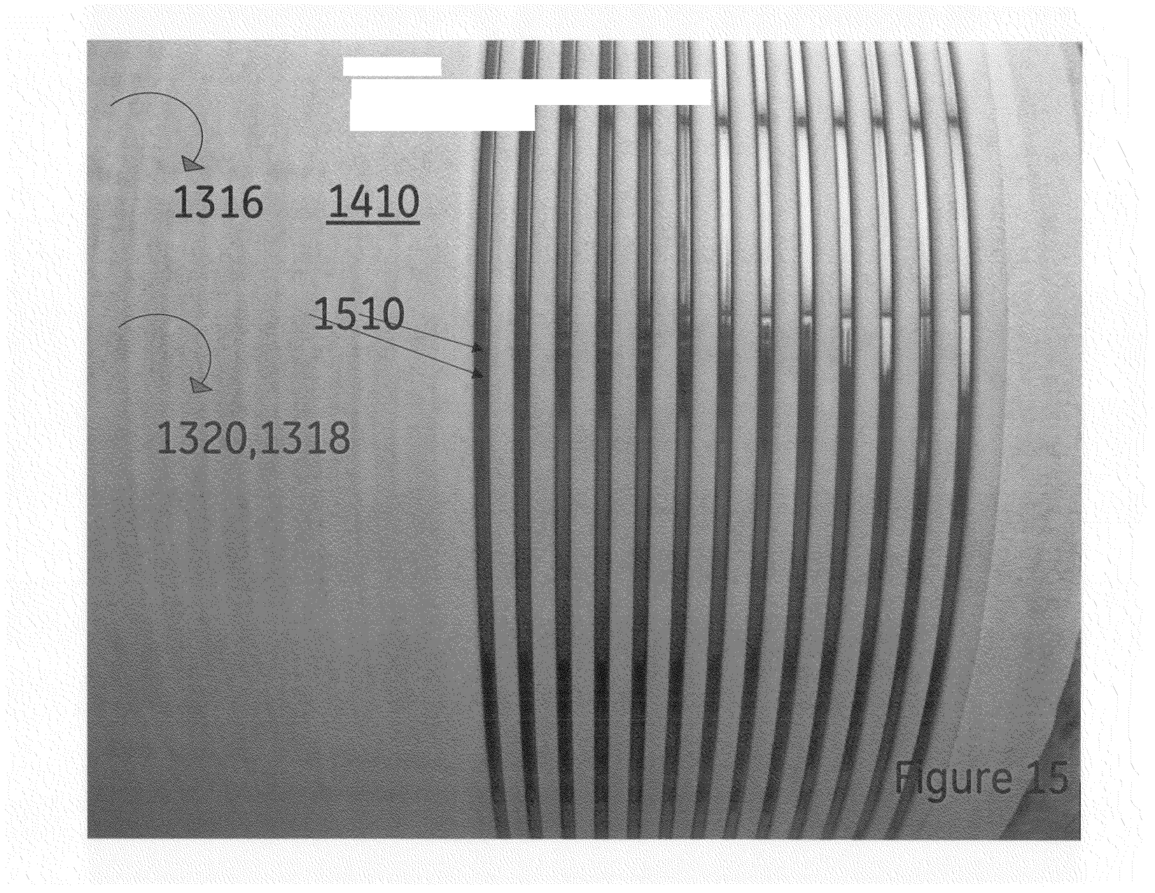

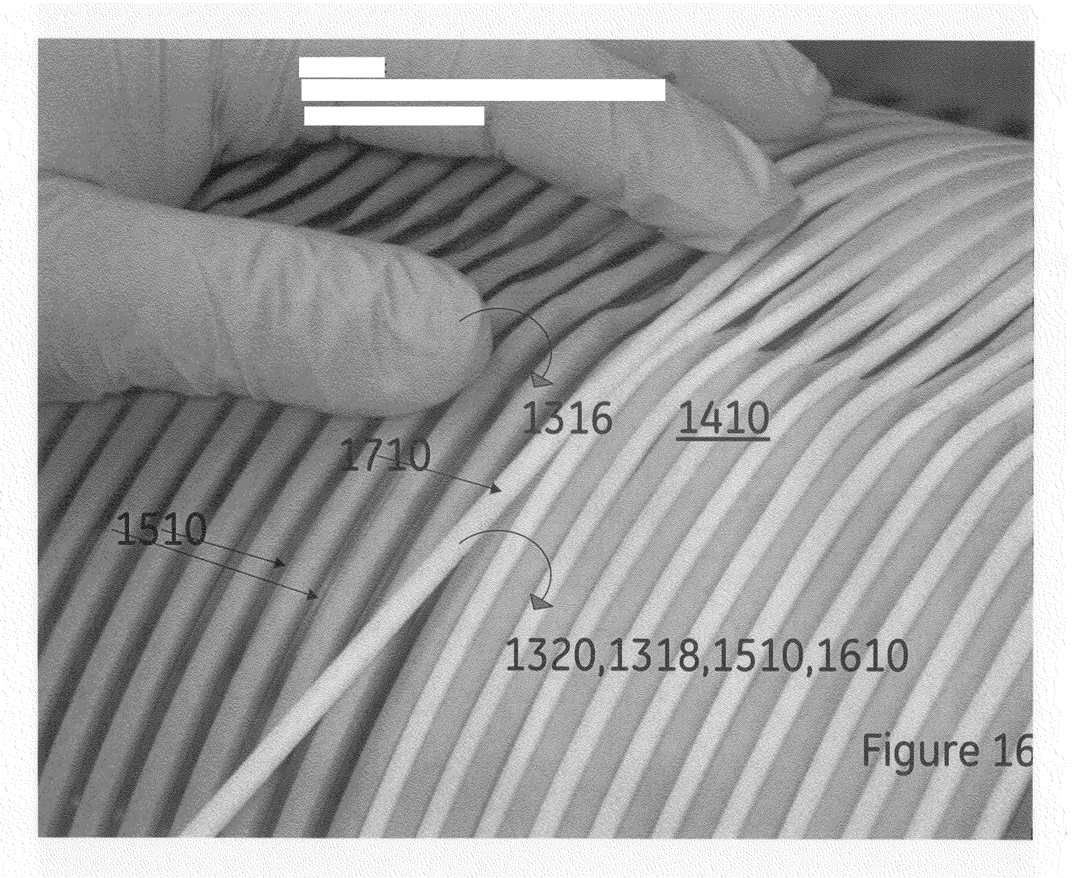

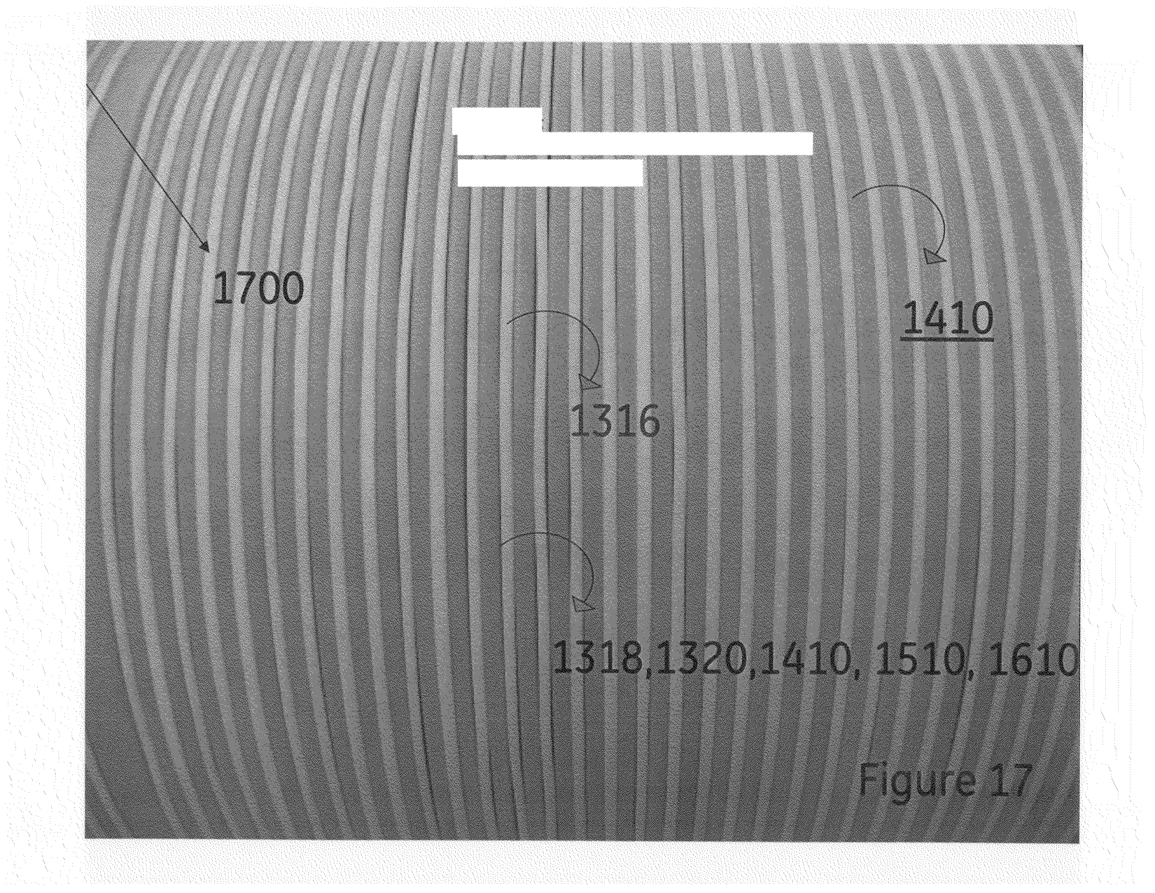

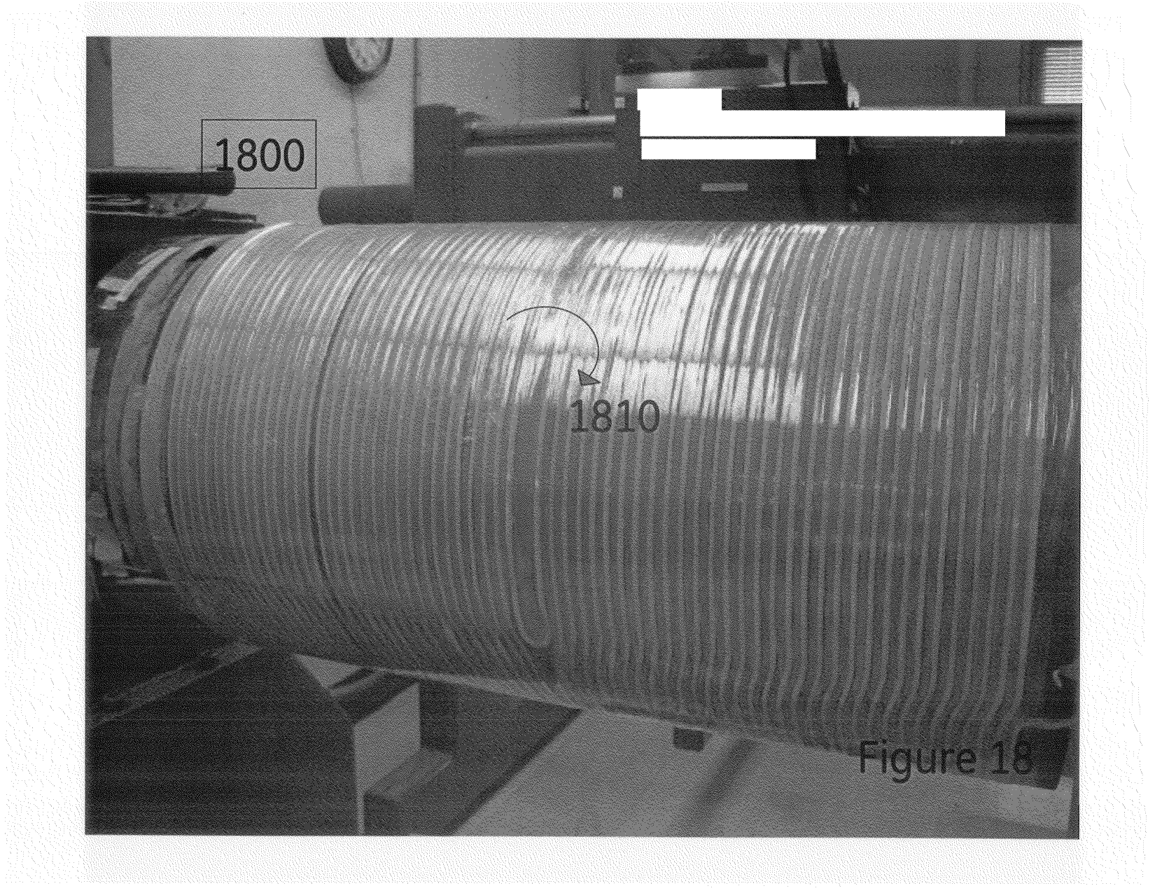

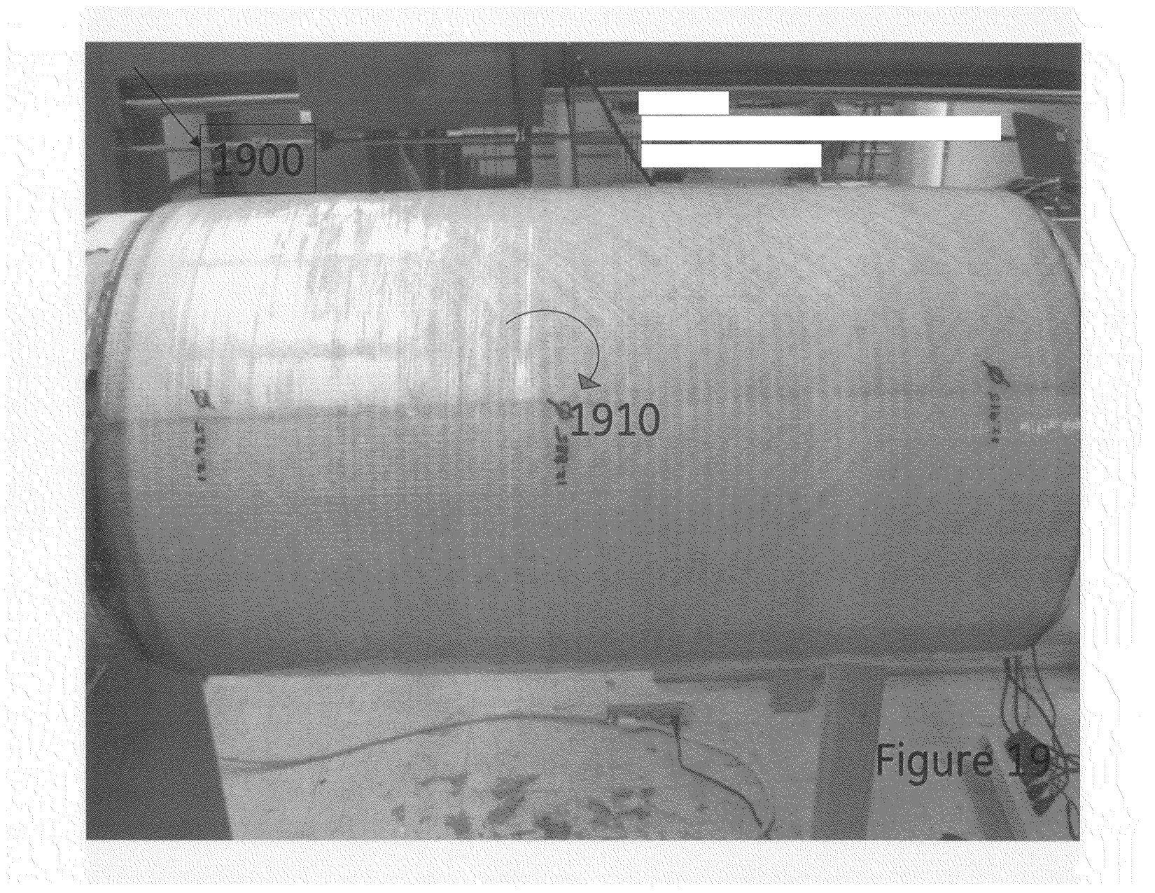

Referring to FIG. 13, a cylindrical element 1300 is provided. The cylindrical element 1310 has an inner surface (not shown in figure) and an outer surface 1312. A plurality of grooves 1314 are disposed on the outer surface of the cylindrical element. The grooves include a plurality of alternately disposed projections 1316 and recesses 1318. A first isolation material 1320, for example, a silicone cord having a thickness of 2 millimeters and a breadth of 4 millimeters, is disposed over the cylindrical element 1310. The first isolation material 1320 is disposed such that the material is aligned to the recesses 1318 on the outer surface of the cylindrical element 1300. Referring to FIG. 14, a second isolation material 1410 is disposed over the cylindrical element 1300. The second isolation material 1410 is disposed such that it covers the entire outer surface 1312 of the cylindrical element including the projections 1316 and the first isolation material 1320 disposed in the recesses 1318. Referring to FIG. 15, a conducting material 1510 is disposed over the second isolation material 1410. The conducting material 1510 is disposed over the cylindrical element such that the conducting material 1510 is aligned to the recesses 1318. The conducting material 1510 is wound over the second isolation material 1410 and is aligned to the first isolation material 1320 disposed in the recesses 1318. Referring to FIG. 16, a third isolation material 1610 is disposed over the conducting material 1510, such that the third isolation material is aligned to the conducting material 1510, the first isolation material 1320 and the recesses 1318. Referring to FIG. 17, a finished surface 1700 of the cylindrical element 1300 with the first, second, and third isolation materials encapsulating the conducting material disposed over the cylindrical element is provided. The finished surface 1700 illustrates alternating bands of the third isolation material 1610 and a portion of the second isolation material 1410 that covers the projections on the outer surface of the cylindrical element. The first isolation material 1320, a portion of the second isolation material covering the recesses and the conducting material are masked below the third isolation material 1610. Referring to FIG. 18, gradient coil assembly 1800 is provided. A protective covering 1810 is disposed over the finished surface 1700 of the cylindrical element 1300. Referring to FIG. 19, gradient coil assembly 1900 is provided. An insulating covering 1910 is disposed over the protective covering 1810 of the cylindrical element 1300.

The gradient coil assembly 1900 was tested in a 3 Tesla field by placing inside a GE Signa 750 MR Magnet. As discussed above, in case of the Z-gradient coil, the Lorenz forces are predominantly radial in direction with some axial component due to the curvature of the static basic magnetic field. The bulk of the isolation material i.e., the first and the second isolation material was applied in the radial direction while the second isolation material provided isolation in the axial direction based on the intensity and the direction of the Lorenz forces.

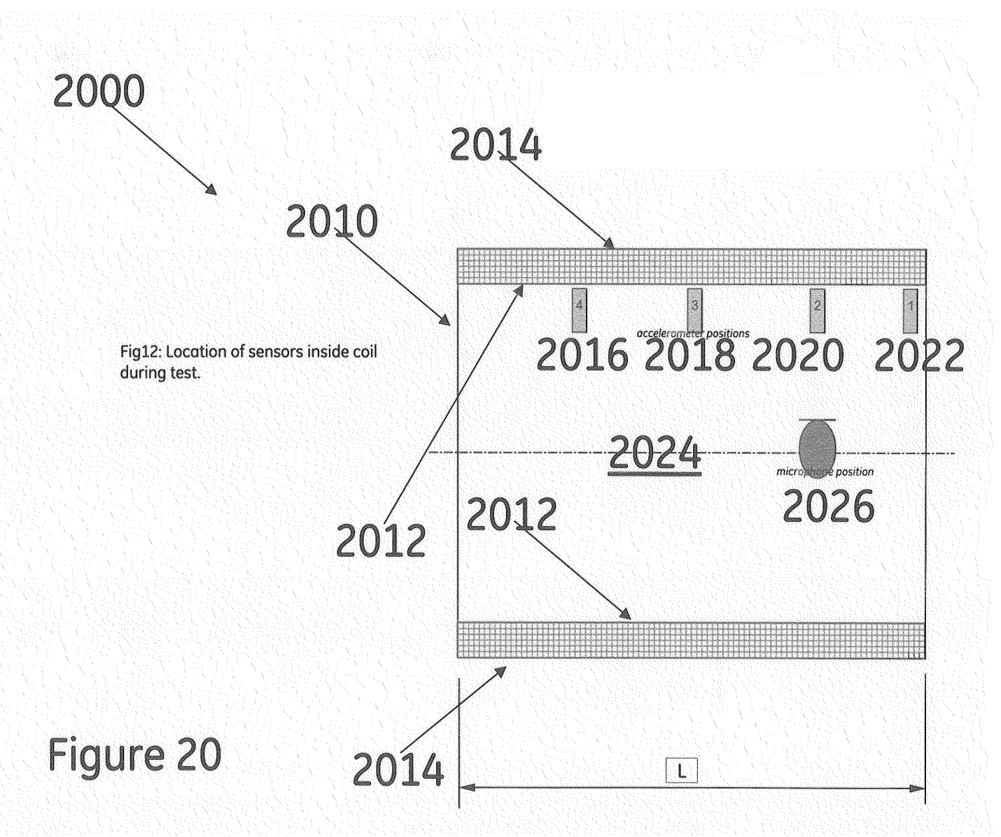

The vibration and noise were measured as illustrated in FIG. 20. FIG. 20 provides a schematic of a gradient coil assembly 2000. The assembly comprises a cylindrical element 2010. The cylindrical element has an inner surface 2012 and an outer surface 2014. The accelerometers 2016, 2018, 2020 and 2022 are placed on the inner surface 2012. An axis 2024 is shown at the center of the cylindrical element which represents the patient location in an operating MRI device. A microphone was placed at the axis. The results were compared to a similar coil that was built in the conventional way. A conventionally built coil consists of a similar grooved cylinder with the conductors embedded directly in the grooves without the presence of the isolation materials, and held in place with a layer of low compliance epoxy/fiberglass. In the case of the conventionally build coil, the conductors are in intimate and solid contact with the cylinder. The vibration at resonance and structure-borne noise at the applied frequencies between 0 hertz and 3200 hertz were recorded.

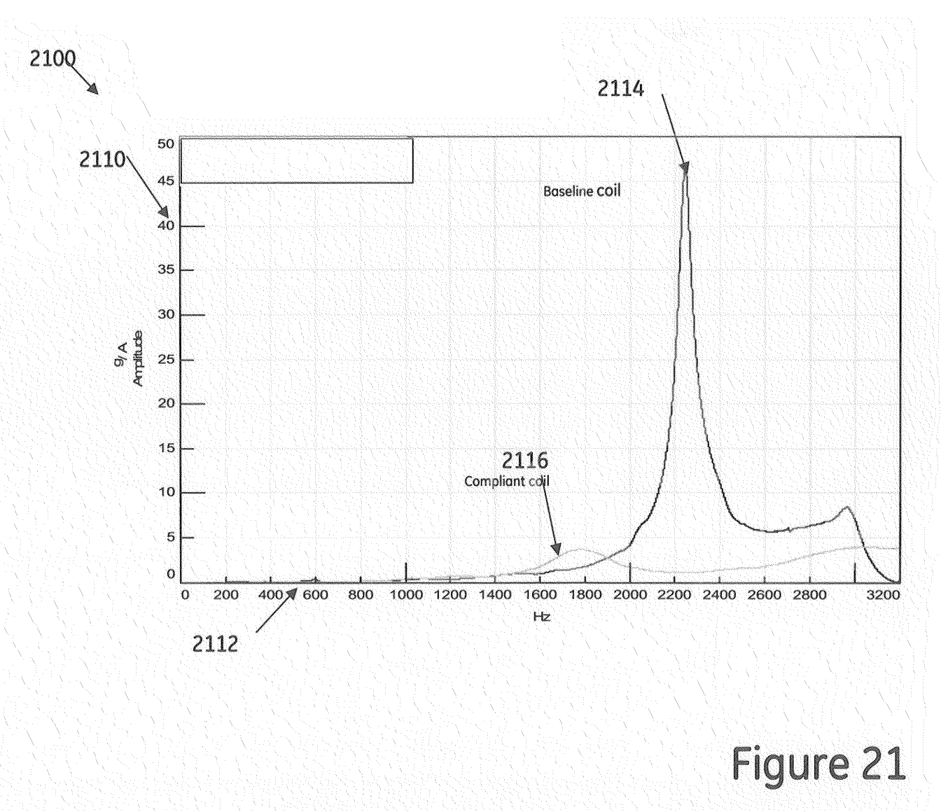

Referring to FIG. 21, a graph 2100 illustrating the vibration at resonance of the gradient coil assembly 1810 in comparison to a conventional coil is provided. The graph 2100 includes amplitude in acceleration g's per ampere on the Y-axis 2110 and frequency in hertz on the X-axis 2112. Curve 2114 represents the vibration at resonance for the gradient coil assembly 1810 and curve 2116 represents the vibration at resonance for the conventional gradient coil assembly. The vibration at resonance was reduced 10 times for curve 2114 when compared to curve 2116 at the applied frequency.

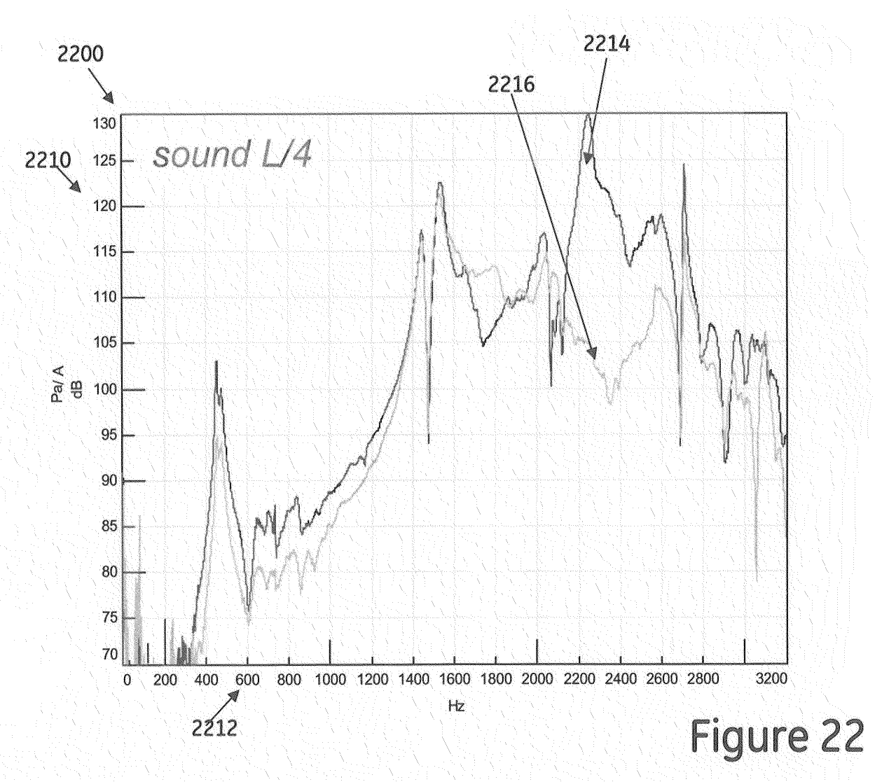

Referring to FIG. 22, a graph 2200 illustrating the air-borne noise of the gradient coil assembly 1810 in comparison to a conventional coil is provided. The graph 1400 includes sound in Pascal per ampere on the Y-axis 2210 and frequency in hertz on the X-axis 2212. Curve 2214 represents the sound at resonance for the gradient coil assembly 1810 and curve 2216 represents the sound at resonance for the conventional gradient coil assembly. The air-borne noise was reduced by 20 decibels for curve 2214, when compared to curve 2216 at the frequencies between 2100 and 2700 Hertz. The sound in the remaining frequencies was found to be produced by other functions of the MRI and was not found related to the vibration of the gradient coils.

In accordance with an embodiment of the invention, a gradient coil assembly 1900 is provided. The gradient coil assembly comprises a cylindrical element. The cylindrical element has an inner surface and an outer surface. A plurality of grooves are disposed on the outer surface of the cylindrical element; wherein the grooves comprise alternately disposed projections and recesses. A first isolation material comprising a silicone cord having compliance in a range from about 0.1 millimeters per Newton to 1.0 millimeter per Newton is disposed over the outer surface of the cylindrical element such that the first isolation material is aligned with the recesses of the cylindrical element. A second isolation material comprising a rubber sheet having compliance in a range from about 1 millimeter per Newton to 10 millimeters per Newton is disposed over the projections on the outer surface of the cylindrical element and the first isolation material. A conducting material is disposed over the second isolation material. The conducting material is aligned with the recesses of the cylindrical element. A third isolation material comprising a silicone cord having compliance in a range from about 0.1 millimeters per Newton to 1.0 millimeter per Newton is disposed over the conducting material. The conducting material is disposed between the second isolation material and the third isolation material.

While the invention has been described in detail in connection with a number of embodiments, the invention is not limited to such disclosed embodiments. Rather, the invention can be modified to incorporate any number of variations, alterations, substitutions or equivalent arrangements not heretofore described, but which are commensurate with the scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

1. A gradient coil assembly comprising:
a cylindrical element, the cylindrical element having an inner surface and an outer surface;
at least one first isolation material disposed over the outer surface of the cylindrical element; and
a conducting material disposed over the isolation material.

2. A gradient coil assembly comprising:
a cylindrical element, the cylindrical element having an inner surface and an outer surface;
a first isolation material disposed over the outer surface of the cylindrical element;
a conducting material disposed over the first isolation material; and
a second isolation material disposed over the conducting material, wherein the conducting material is disposed between the first isolation material and the second isolation material.

3. The assembly of claim 2, wherein the second isolation material is disposed over the conducting material in the form of a sleeve.

4. The assembly of claim 2, wherein the second isolation material is encapsulates the conducting material.

5. A gradient coil assembly comprising:
a cylindrical element, the cylindrical element having an inner surface and an outer surface;
a first isolation material disposed over the outer surface of the cylindrical element;
a second isolation material disposed over the first isolation material;
a conducting material disposed over the second isolation material; and
a third isolation material disposed over the conducting material; wherein the conducting material is disposed between the second isolation material and the third isolation material.

6. The assembly of claim 5, wherein the second isolation material is disposed over the conducting material in the form of a sleeve.

7. The assembly of claim 5, wherein the second isolation material encapsulates the conducting material.

8. The assembly of claim 5, wherein the cylindrical element comprises a material selected from epoxy or fiberglass.

9. The assembly of claim 5, wherein a plurality of grooves are disposed on the outer surface of the cylindrical element; wherein the grooves comprise alternately disposed projections and recesses.

10. The assembly of claim 5, wherein the conducting material comprises copper.

11. The assembly of claim 5, wherein the first isolation material comprises a material having compliance in a range from about 0.1 millimeters per Newton to about 1 millimeter per Newton.

12. The assembly of claim 5, wherein the second isolation material comprises a material having compliance in a range from about 1 millimeter per Newton to about 10 millimeters per Newton.

13. The assembly of claim 5, wherein the third isolation material comprises a material having compliance in a range from about 0.1 millimeters per Newton to about 1 millimeter per Newton.

14. The assembly of claim 5, wherein the first isolation material comprises silicone, rubber, or compliant epoxy.

15. The assembly of claim 5, wherein the second isolation material comprises silicone, rubber, or compliant epoxy

16. The assembly of claim 5, wherein the third isolation material comprises silicone, rubber, or compliant epoxy.

17. The assembly of claim 5, wherein the assembly is component of a magnetic resonance imaging device.

18. The assembly of claim 5, further comprising a protective covering.

19. The assembly of claim 5, further comprising an insulating covering.

20. An apparatus comprising:
at least one component contributing to generation of mechanical oscillations; wherein the component comprises:
a cylindrical element, the cylindrical element having an inner surface and an outer surface;
at least one first isolation material disposed over the outer surface of the cylindrical element; and
a conducting material disposed over the isolation material.

21. The apparatus of claim 20, further comprising a second isolation material disposed over the conducting material; wherein the conducting material is disposed between the at lest one isolation material and the second isolation material.

22. The apparatus of claim 20, further comprising a third isolation material disposed over the second isolation material.

23. The apparatus of claim 20, wherein the component comprises a gradient coil system

24. A magnetic resonance imaging device comprising:
a magnet;
a gradient coil assembly located within the magnet; wherein the gradient coil assembly comprises,
a cylindrical element, the cylindrical element having an inner surface and an outer surface;
a cylindrical element, the cylindrical element having an inner surface and an outer surface;
at least one first isolation material disposed over the outer surface of the cylindrical element; and
a conducting material disposed over the isolation material.

25. The device of claim 24, further comprising a second isolation material disposed over the conducting material; wherein the conducting material is disposed between the at lest one isolation material and the second isolation material.

26. The device of claim 24, further comprising a third isolation material disposed over the second isolation material.

27. A gradient coil assembly comprising:
a cylindrical element, the cylindrical element having an inner surface and an outer surface;
a plurality of grooves disposed on the outer surface of the cylindrical element;
wherein the grooves comprise alternately disposed projections and recesses;
a first isolation material comprising silicone, rubber, or compliant epoxy having compliance in a range from about 0.1 millimeters per Newton to about 1 millimeter per Newton disposed over the outer surface of the cylindrical element, wherein the first isolation material is aligned with the recesses of the cylindrical element;
a second isolation material comprising silicone, rubber, or compliant epoxy having compliance in a range from about 1 millimeters per Newton to about 10 millimeter per Newton disposed over the projections on the outer surface of the cylindrical element and the first isolation material;
a conducting material disposed over the first isolation material, wherein the conducting material is aligned with the recesses of the cylindrical element; and
a third isolation material comprising silicone, rubber, or compliant epoxy having compliance in a range from about 0.1 millimeters per Newton to about 1 millimeter per Newton disposed over the conducting material; wherein the conducting material is disposed between the second isolation material and the third isolation material.

28. A method of forming a gradient coil assembly comprising:
providing a cylindrical element having an inner surface and an outer surface;
disposing at least one first isolation material over the outer surface of the cylindrical element, and
disposing a conducting material over the isolation material.

29. A method of forming a gradient coil assembly comprising:
providing a cylindrical element having an inner surface and an outer surface;
wherein a plurality of grooves are disposed on the outer surface of the cylindrical element;
wherein the grooves comprise alternately disposed projections and recesses;
disposing a first isolation material over the outer surface of the cylindrical element, wherein the first isolation material is aligned with the recesses of the cylindrical element;
disposing a second isolation material over the surface of the cylindrical element, wherein the second isolation material covers the projections on the outer surface of the cylindrical element and the first isolation material aligned with the recesses of the cylindrical element;
disposing a conducting material over the second isolation material, wherein the conducting material is aligned with the recesses of the cylindrical element; and
disposing a third isolation material over the conducting material; wherein the conducting material is disposed between the second isolation material and the third isolation material.
